(19) United States
(12) Patent Application Publication
(10) Pub. No.: US 2025/0080154 A1
(43) Pub. Date: Mar. 6, 2025

(54) ELECTRONIC CIRCUIT FOR MULTI-BAND TRANSMITTING / RECEIVING

(71) Applicant: SAMSUNG ELECTRONICS CO., LTD., SUWON-SI (KR)

(72) Inventors: WOOSEOK LEE, Suwon-si (KR); JEONGYEOL BAE, Suwon-si (KR); SANGMIN YOO, Suwon-si (KR); JONGSOO LEE, Suwon-si (KR)

(21) Appl. No.: 18/739,418

(22) Filed: Jun. 11, 2024

(30) Foreign Application Priority Data
Aug. 31, 2023 (KR) 10-2023-0115738
Oct. 11, 2023 (KR) 10-2023-0134618

(51) Int. Cl. H04B 1/40; H03F 3/45; H04B 1/00

(52) U.S. Cl. CPC H04B 1/40; H03F 3/45475; H04B 1/006

(57) ABSTRACT

An electronic circuit includes a first inductor connected to an input terminal, a second inductor and a third inductor connected in series to each other and connected in parallel with the first inductor, a first switch connected between the second inductor and the third inductor, and a processor electrically connected to the first switch. The processor may be configured to close the first switch in response to a first request such that a first signal in a first frequency band is output through an output side of the electronic circuit, and to open the first switch in response to a second request, distinct from the first request, such that a second signal in a second frequency band, lower than the first frequency band, is output through the output side.

### CROSS-REFERENCE TO RELATED APPLICATION(S)

This U.S. non-provisional application claims priority under 35 USC § 119 to Korean Patent Application Nos. 10-2023-0115738, filed on Aug. 31, 2023, and 10-2023-0134618, filed on Oct. 11, 2023, in the Korean Intellectual Property Office, the disclosures of which are herein incorporated by reference in their entireties.

### TECHNICAL FIELD

Example embodiments relate to an electronic circuit for transmitting and/or receiving signals in different frequency bands.

### DISCUSSION OF RELATED ART

Recently developed electronic devices support a plurality of wireless communication technologies to provide users with a variety of services. Since wireless communication technologies use different frequency bands depending on the type, electronic devices include radio-frequency integrated circuits (RFICs) to support a plurality of wireless communication technologies.

With the recent evolution of wireless communications from third generation (3G) and long-term evolution (LTE) to 5G, the frequency bands required for RFICs have increased.

Additionally, Wi-Fi communication technology is evolving to allow electronic devices to connect to wireless local area networks (WLANs). For example, electronic devices support Wi-Fi 6E and Wi-Fi 7 with the development of standards related to Wi-Fi communication technology. As a result, RFICs included in electronic devices support Wi-Fi communication in a 6 GHz band in addition to a 2.4 GHz band and a 5 GHz band.

Accordingly, RFICs may include a plurality of transceivers (sometimes called RF chains), corresponding to each frequency band, to support communications using signals in different frequency bands.

This may lead to an increase in size of an RFIC chip. Additionally, circuit loss may occur due to devices included in each transceiver of the RFIC, which may reduce operating efficiency of the RFIC.

### SUMMARY

Example embodiments provide an electronic circuit controlling a switch, connected to an inductor, to transmit or receive signals in different frequency bands.

According to an example embodiment, an electronic circuit includes a first inductor connected to an input terminal, a second inductor and a third inductor connected in series and connected in parallel with the first inductor, a first switch connected between the second inductor and the third inductor, and a processor electrically connected to the first switch. The processor may be configured to close the first switch in response to a first request such that a first signal in a first frequency band is output through an output side of the electronic circuit, and to open the first switch in response to a second request, distinct from the first request, such that a second signal in a second frequency band, lower than the first frequency band, is output through the output side.

According to an example embodiment, a transmitting circuit system including an electronic circuit includes a transmission mixer configured to up-convert a baseband signal, a first transmission circuit configured to receive a signal up-converted from the baseband signal by the transmission mixer, an amplifier configured to amplify a signal output from the first transmission circuit and to output the amplified signal, a second transmission circuit having an output side and receiving an amplified signal from the amplifier, and a processor electrically connected to the first transmission circuit and the second transmission circuit. The first transmission circuit may include a first inductor, a second inductor and a third inductor connected in parallel to the first inductor and connected in series, and a first switch connected between the second inductor and the third inductor. The processor may control the first switch such that signals in different frequency bands are output through the output terminal.

According to an example embodiment, a receiving circuit system includes a first receiving circuit configured to receive a radio-frequency (RF) signal at a receiving terminal, a low-noise amplifier configured to amplify a signal output from the first receiving circuit, a second receiving circuit configured to receive a signal amplified by the low-noise amplifier, a receiving mixer configured to down-convert a signal, output from the second receiving circuit, into a baseband signal, and a processor connected to the first receiving circuit and the second receiving circuit. The first receiving circuit may include a first receiving inductor, a second receiving inductor and a third receiving inductor connected in parallel with the first receiving inductor, and a receiving switch connected between the second receiving inductor and the third receiving inductor, where the second and third receiving inductors are connected in series when the receiving switch is closed. The processor may control the first receiving switch to change inductance of the first receiving circuit such that signals in different frequency bands, received through the receiving terminal, are output through the first receiving circuit.

According to an example embodiment, an electronic circuit includes: a first inductor connected to an input side of the electronic circuit; a second inductor; a switch connected in series with the second inductor, wherein the switch and the second conductor are together connected in parallel with the first inductor; and a processor electrically connected to the switch and configured to: close the switch when a first signal in a first frequency band is input to the electronic circuit, to enable the first signal to be transmitted through an output side of the electronic circuit; and open the switch when a second signal in a second frequency band, lower than the first frequency band, is input at the input side, to enable the second signal to be transmitted through the output side. The first and second inductors have inductances sufficient to improve an impedance match, within the first frequency band and/or the second frequency band, between external circuitry connected to the input side and external circuitry connected to the output side.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram of a electronic circuit system according to an example embodiment.

FIG. 2A is a circuit diagram illustrating an example of an electronic circuit included in the transmission circuit system of FIG. 1.

FIG. 2B is a circuit diagram illustrating a configuration in which the electronic circuit of FIG. 2A further includes a variable capacitor connected in parallel with a first inductor.

FIG. 2C is a circuit diagram illustrating a configuration in which the electronic circuit of FIG. 2B further includes inductors connected in parallel with a first inductor.

FIG. 3 is a circuit diagram illustrating another example of an electronic circuit included in the electronic circuit system of FIG. 1.

FIG. 4 is a circuit diagram of a electronic circuit system including a first transmission circuit and a second transmission circuit according to an example embodiment.

FIG. 5 is a block diagram of a receiving circuit system according to an example embodiment.

FIG. 6 is a circuit diagram illustrating an example of a first receiving circuit in the receiving circuit system of FIG. 5.

FIG. 7 is a circuit diagram illustrating an example of a second receiving circuit in the receiving circuit system of FIG. 5.

FIG. 8 is a block diagram of a transceiver system according to an example embodiment.

FIG. 9 is a block diagram of an IoT device including an electronic circuit system according to an example embodiment.

FIG. 10 is a block diagram of a mobile terminal to which an electronic circuit system according to an example embodiment is applied.

### DETAILED DESCRIPTION

Hereinafter, example embodiments will be described with reference to the accompanying drawings.

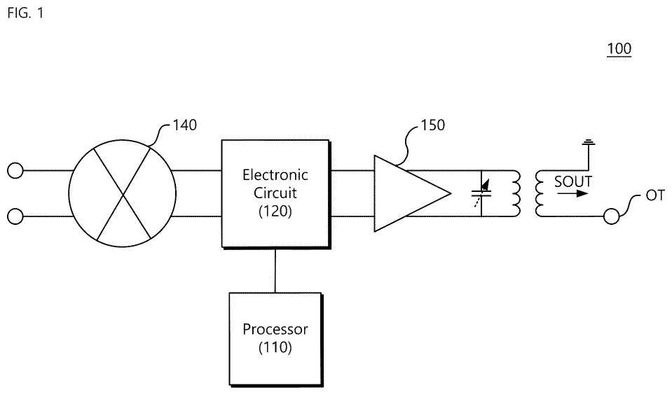

FIG. 1 is a block diagram of an electronic circuit system, 100, according to an example embodiment. An electronic circuit system 100 may include an electronic circuit 120 configured to transmit signals in different frequency bands; a mixer 140; an amplifier 150; and a processor 110.

The electronic circuit system 100 may include a transmission mixer 140 that up-converts a baseband signal. For example, the transmission mixer 140 may up-convert a baseband signal into a radio-frequency (RF) signal with a specified frequency, based on a signal received from a local oscillator.

In addition, the electronic circuit system 100 may include an electronic circuit 120 connected to the transmission mixer 140.

The electronic circuit 120 may receive a signal output from the transmission mixer 140. For example, the electronic circuit 120 may receive a signal up-converted from the baseband signal by the transmission mixer 140.

The electronic circuit 120 may function as an impedance matching circuit for impedance matching between circuitry connected to the input side of the electronic circuit 120 (e.g., the transmission mixer 140) and circuitry connected to the output side of the electronic circuit 120 (e.g., the amplifier 150). As compared to a system in which the electronic circuit 120 does not exist between the transmission mixer 140 and the amplifier 150, impedance matching may be improved in at least one of the frequency bands within which output signals SOUT are transmitted.

For example, the signal output from the transmission mixer 140 may be converted into a signal in a predetermined frequency band through the electronic circuit 120. Also, the signal output from the transmission mixer 140 may be converted by the transmission mixer 140. Furthermore, the electronic circuit 120 may transmit the signal in the predetermined frequency band to the amplifier 150.

The electronic circuit system 100 may include a processor 110, electrically connected to the electronic circuit 120.

The processor 110 may execute software (or a program) to control at least one other component (for example, the electronic circuit 120) of the electronic circuit system 100, and may process various data processing or computation.

The processor 110 may include a central processing unit, a microprocessor, or the like, and may control the overall operation of the electronic circuit system 100. Accordingly, the operations performed by the electronic circuit system 100 below may be understood as being performed under the control of the processor 110.

According to an example embodiment, the processor 110 may execute an algorithm for controlling the electronic circuit 120. For example, the algorithm may be a software code programmed inside the processor 110. For example, the algorithm may be a hard code hard-coded inside the processor 110, but example embodiments are not limited thereto.

The processor 110 may control a switch included in the electronic circuit 120 based on the algorithm. For example, the processor 110 may close or open the switch included in the electronic circuit 120.

The processor 110 may control a switch, included in the electronic circuit 120, such that the electronic circuit system 100 transmits output signals SOUT in different frequency bands (e.g., non-simultaneously) at an output terminal OT.

For example, the processor 110 may close the switch included in the electronic circuit 120 such that the electronic circuit system 100 transmits a signal SOUT in a first frequency band at the output terminal OT.

In addition, the processor 110 may open the switch included in the electronic circuit 120 such that the electronic circuit system 100 transmits a signal SOUT in a second frequency band at the output terminal OT.

Accordingly, the electronic circuit system 100 may transmit signals in different frequency bands through a single transmission structure including the transmission mixer 140, the electronic circuit 120, and the amplifier 150. Analogous circuitry may be provided in accordance with the inventive concept for receive operations within a transceiver, as described below.

As a result, the electronic circuit system 100 according to an example embodiment may have a significantly reduced area.

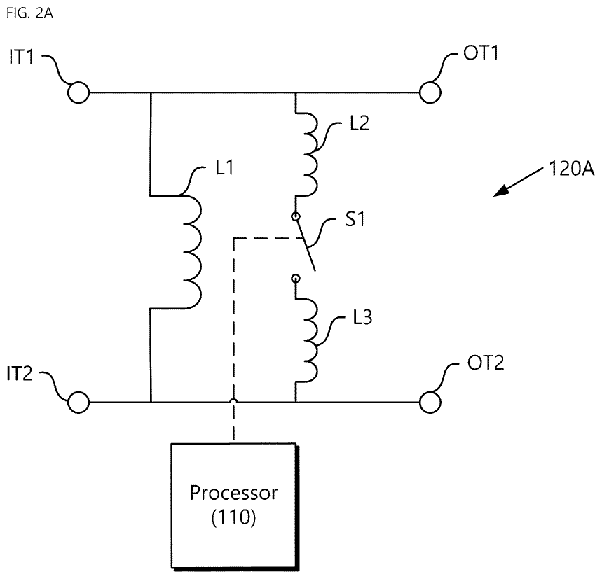

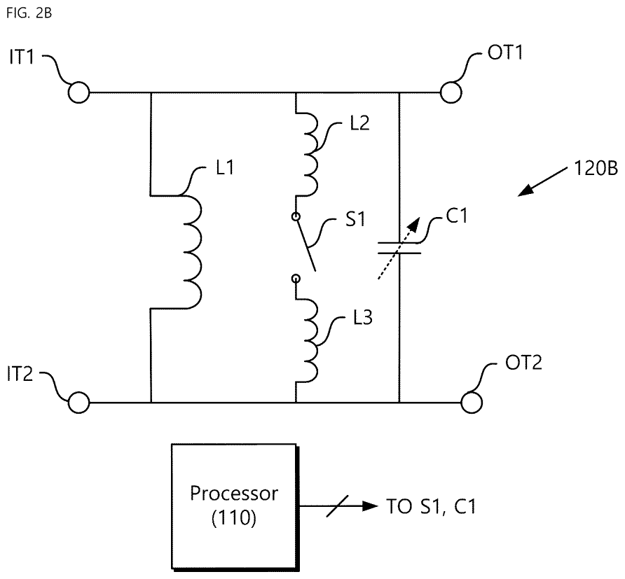

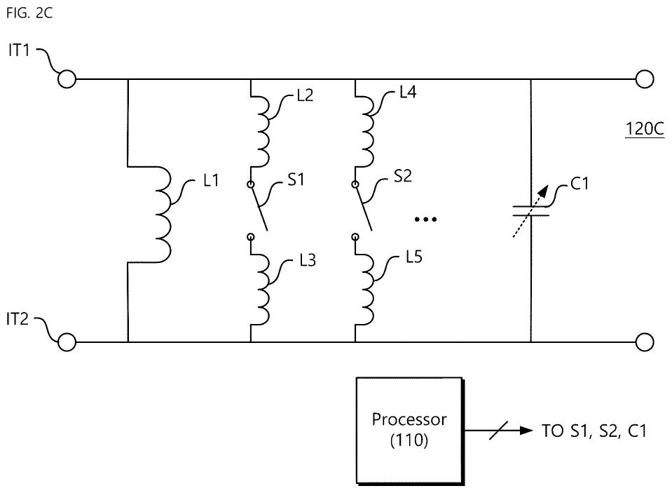

Referring to FIG. 2A, an electronic circuit 120A according to an example embodiment may include a plurality of inductors L1, L2, and L3. The electronic circuit 120A illustrated in FIG. 2A is an example of the electronic circuit 120 of FIG. 1A.

The electronic circuit 120A may include a first inductor L1 connected to input terminals IT1 and IT2 (an input side of the electronic circuit 120A). An output side of the electronic circuit 120A includes output terminals OT1 and OT2. The first inductor L1 may be connected to the transmission mixer 140 through the first input terminal IT1 and the second input terminal IT2.

The electronic circuit 120A may include a second inductor L2 and a third inductor L3 connected in parallel with the first inductor L1. The second inductor L2 and the third inductor L3 may be connected to each other in series (an electrical connection in series is made between them when the first switch S1, described below, is closed).

In addition, the electronic circuit 120A may include a first switch S1 connected between the second inductor L2 and the third inductor L3.

According to an example embodiment, the processor 110 may control the first switch S1, included in the electronic circuit 120A, such that a signal in a specified frequency band is output through the output side of the circuit 120A, and transmitted at the output terminal OT of the transmitting circuit system 100.

For example, the processor 110 may close the first switch S1 in response to a first request for transmitting a first signal in a first frequency band (for example, about 6 GHZ). (Herein, a “request” acted upon by the processor 110 is not necessarily a request from an external circuit or source. For instance, a “request” for transmitting the first signal, which request is responded to by the processor 110, could be any determination by the processor 110 that the first signal in the first frequency band is output by the transmission mixer 140.) The electronic circuit 120A may output the first signal in the first frequency band through its output side while the first switch S1 is closed.

In addition, the processor 110 may open the first switch S1 in response to a second request for transmitting a second signal in a second frequency band lower than the first frequency band (for example, about 5 GHz). The electronic circuit 120 may output the second signal in the second frequency band through its output side while the first switch S1 is open.

Referring to the above-described components, the processor 110 according to an example embodiment may control the first switch S1, included in the electronic circuit 120A, to transmit signals having different frequency bands at the output terminal OT.

Accordingly, the electronic circuit system 100 may transmit signals in different frequency bands through a single transmission structure (or a TX chain) including the transmission mixer 140, the electronic circuit 120A, and an amplifier 150.

As a result, the electronic circuit system 100 may have a significantly reduced area.

FIG. 2B is a circuit diagram illustrating a configuration in which the electronic circuit of FIG. 2A further includes a variable capacitor connected in parallel with a first inductor, and FIG. 2C is a circuit diagram illustrating a configuration in which the electronic circuit of FIG. 2B further includes inductors connected in parallel with a first inductor.

Referring to FIG. 2B, an electronic circuit 120B may further include a variable capacitor C1 connected to a plurality of inductors L1, L2, and L3. It is noted here that the inductors L1 to L3, as well as the other inductors described herein, may be discrete element inductors (sometimes called lumped elements), which may be smaller in size than distributed inductors formed by open circuit stubs or short circuited stubs.

For example, the electronic circuit 120B may include a variable capacitor C1 connected in parallel with the first inductor L1, the second inductor L2, and/or the third inductor L3.

For example, the electronic circuit 120B may include a variable capacitor C1 controlled to have a first capacitance, connected in parallel with the first inductor L1 while a first switch S1 is open.

In addition, the electronic circuit 120B may include the variable capacitor C1, controlled to have a second capacitance, connected in parallel with the first inductor L1 and connected in parallel with the second inductor L2 and the third inductor L3 while the first switch S1 is closed.

According to an example embodiment, the processor 110 may control capacitance of the variable capacitor C1, included in the electronic circuit 120B, such that a signal in a specified frequency band is transmitted at the output terminal OT.

For example, the processor 110 may control the capacitance of the variable capacitor C1 such that the variable capacitor C1 resonates with at least one of the inductors connected to the variable capacitor C1.

For example, the processor 110 may control the capacitance of the variable capacitor C1 to be set to a first capacitance such that the variable capacitor C1 resonates with the first inductor L1, the second inductor L2, and the third inductor L3 while the first switch is closed.

In addition, the processor 110 may control the capacitance of the variable capacitor C1 to be set to second capacitance, lower than the first capacitance, such that the variable capacitor C1 resonates with the first inductor L1 while the first switch S1 is open.

Referring to the above-described components, the processor 110 according to an example embodiment may control the capacitance of the variable capacitor C1 based on an inductance value of the electronic circuit 120 controlled through the first switch S1.

Accordingly, the processor 110 may significantly reduce the number and/or size of capacitors required in the electronic circuit 120 to transmit signals in different frequency bands. In addition, the processor 110 may significantly reduce loss caused by a capacitor included in the electronic circuit 120.

As a result, the electronic circuit system 100 according to an example embodiment may improve power efficiency of an operation for transmitting signals in different frequency bands. In addition, the electronic circuit system 100 according to an example embodiment may improve the gain of the electronic circuit 120B.

Referring to FIG. 2C, an electronic circuit 120C according to an example embodiment may include a plurality of inductors L2, L3, L4, and L5, connected in parallel with a first inductor L1, and a plurality of switches S1 and S2 connected between the inductors.

The electronic circuit 120C illustrated in FIG. 2C may be understood as an example of the electronic circuit 120 of FIG. 1.

In addition, the electronic circuit 120C illustrated in FIG. 2C may be understood as further including a plurality of inductors L4 and L5 connected in parallel with the first inductor L1, the second inductor L3, and the third inductor L3, and a second switch S2 connected between the corresponding inductors LA and LA, in the configuration of the electronic circuit 120B of FIG. 2B

Therefore, the same reference numerals are used to denote the same or substantially the same components, and redundant descriptions will be omitted.

The electronic circuit 120C according to an example embodiment may include a fourth inductor LA and a fifth inductor L5 connected in parallel with the first inductor L1. The fourth inductor LA and the fifth inductor L5 may be connected in series.

The electronic circuit 120C may further include a second switch S2 connected between the fourth inductor LA and the fifth inductor L5.

According to an example embodiment, the processor 110 may control at least one of the switches S1 and S2, included in the electronic circuit 120C, such that the output signal in a specified frequency band is transmitted through at output terminal OT.

For example, the processor 110 may close or open at least one of the first switch S1 and the second switch S2 such that a signal in a specified frequency band is transmitted at an output terminal OT.

For example, the processor 110 may close the first switch S1 included in the electronic circuit 120A and open the second switch S2 included in the electronic circuit 120A in response to a first request for transmitting a first signal having a first frequency band.

The processor 110 may transmit a first signal having a first frequency band at the output terminal OT while the first switch S1 is closed and the second switch S2 is open.

In addition, the processor 110 may close the first switch S1 and the second switch S2 in response to a third request for transmitting a third signal having a third frequency band, higher than the first frequency band.

The processor 110 may transmit a third signal having a third frequency band at the output terminal OT while the first switch S1 and the second switch S2 are closed.

In addition, the processor 110 may open the first switch S1 and close the second switch S2 in response to a fourth request for transmitting the fourth signal having the fourth frequency band, higher than the first frequency band and lower than the third frequency band. The processor 110 may transmit the fourth signal having the fourth frequency band at the output terminal OT while the first switch S1 is open and the second switch S2 is closed.

For example, the sum of inductance of the second inductor L2 and inductance of the third inductor L3 may be referred to as being smaller than the sum of inductance of the fourth inductor LA and inductance of the fifth inductor L5.

In addition, the processor 110 may open the first switch S1 and the second switch S2 in response to a second request for transmitting a second signal in a second frequency band, lower than the first frequency band. The processor 110 may transmit a second signal in the second frequency band at the output terminal OT while the first switch S1 and the second switch S2 are open.

However, the number and configuration of inductors connected in parallel with the first inductor L1 are not limited to the above-described examples.

Referring to the above-described components, the processor 110 according to an example embodiment may control a plurality of switches (for example, the first switch S1 and the second switch S2), included in the electronic circuit 120C, to transmit a plurality of signals having different frequency bands at the output terminal OT.

Accordingly, the electronic circuit system 100 may transmit signals in different frequency bands through a single transmission structure (or a TX chain) including a transmission mixer 140, the electronic circuit 120C, and an amplifier 150.

As a result, the electronic circuit system 100 may have a significantly reduced area.

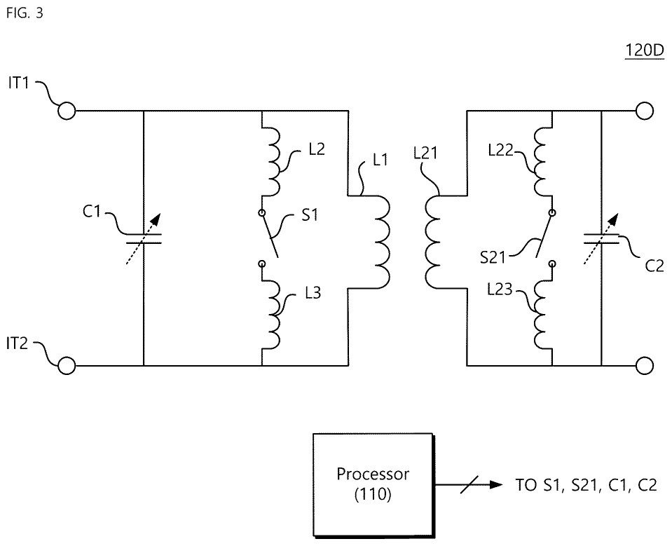

FIG. 3 is a circuit diagram illustrating another example of an electronic circuit included in the electronic circuit system of FIG. 1.

Referring to FIG. 3, an electronic circuit 120D according to an example embodiment may include inductors L1 and L21, connected to each other, and a plurality of inductors L2, L3, L22, and L23 connected in parallel with each of the inductors L1 and L21

The electronic circuit 120D illustrated in FIG. 3 may be understood as an example of the electronic circuit 120 of FIG. 1.

In addition, the electronic circuit 120D illustrated in FIG. 3 may be understood as further including a first output side inductor L21, a second output side inductor L22, a third output side inductor L23, and an output side switch S21, in the configuration of the electronic circuit 120B of FIG. 2A.

Therefore, the same reference numerals are used to denote the same or substantially the same components, and redundant descriptions will be omitted.

According to an example embodiment, the electronic circuit 120D may include a first output side inductor L21 electromagnetically coupled to the first inductor L1.

In addition, the electronic circuit 120D may include a second output side inductor L22 and a third output side inductor L23 connected in parallel with the first output side inductor L21. The second output side inductor L22 and the third output side inductor L23 may be connected to each other in series.

In addition, the electronic circuit 120D may include an output side switch S21 connected between the second output side inductor L22 and the third output side inductor L23.

The electronic circuit 120D may function as an impedance matching circuit for impedance matching of a signal transmitted through an output terminal OT. For example, a signal output through a transmission mixer 140 may be converted into a signal having specified transmission power through the electronic circuit 120D.

According to an example embodiment, the processor 110 may control the first switch S1 and/or the output side switch S21, included in the electronic circuit 120D, such that an output signal SOUT is transmitted with specified transmission power.

For example, the processor 110 may close the first switch S1 in response to a request to increase transmission power of an output signal SOUT.

In addition, the processor 110 may open the first switch S1 in response to a request to decrease the transmission power of the output signal SOUT.

For example, the processor 110 may close the first switch S1 in response to a request to transmit a signal with the first transmission power.

In addition, the processor 110 may open the first switch S1 in response to a request to transmit a signal with second transmission power, lower than the first transmission power.

For example, the processor 110 may close the first switch S1 to increase the transmission power of the output signal SOUT. In addition, the processor 110 may open the first switch S1 to decrease the transmission power of the output signal SOUT.

For example, the processor 110 may open the output side switch S21 in response to a request to increase the transmission power of the output signal SOUT.

In addition, the processor 110 may close the output side switch S21 in response to a request to decrease the transmission power of the output signal SOUT.

For example, the processor 110 may open the output side switch S21 to increase the transmission power of the signal transmitted at the output terminal OT. In addition, the processor 110 may close the output side switch S21 to decrease the transmission power of the output signal SOUT.

For example, the processor 110 may close the switch S1 and open the output side switch S21 in response to a request to increase the transmission power of the signal transmitted through output terminal OT.

In addition, the processor 110 may open the first switch S1 and close the output side switch S21 in response to a request to decrease the transmission power of the output signal SOUT.

Referring to the above-described components, the processor 110 according to an embodiment may control the first switch S1 and/or the output side switch S21, included in the electronic circuit 120D, to control the transmission power of the output signal SOUT.

Accordingly, the electronic circuit system 100 may transmit signals with different transmission powers through a single transmission structure (or a TX chain) including a transmit mixer 140, the electronic circuit 120D, and an amplifier 150.

As a result, the electronic circuit system 100 according to an example embodiment may have a significantly reduced area.

In addition, the electronic circuit 120D may further include an output side variable capacitor C2 connected to the first output side inductor L21, the second output side inductor L22, and the third output side inductor L23.

In this case, the processor 110 may control capacitance of the output side variable capacitor C2 such that the output side variable capacitor C2 resonates with at least one of the output side inductors L21, L22, and L23 connected to the output side variable capacitor C2.

For example, when the output side switch S21 is open, the processor 110 may control the capacitance of the output side variable capacitor C2 such that the output side variable capacitor C2 resonates with the first output side inductor L21.

In addition, when the output side switch S21 is closed, the processor 110 may control the capacitance of the output side variable capacitor C2 such that the output side variable capacitor C2 resonates with the first output side inductor L21, the second output side inductor L22, and the third output side inductor L23.

Referring to the above-described configurations, the processor 110 according to an example embodiment may control the capacitance of the output side variable capacitor C2 to transmit a signal having a specified frequency, based on the inductance determined by controlling at least one switch.

Accordingly, the processor 110 may significantly decrease the number and/or size of capacitors required in the electronic circuit 120D to transmit signals in different frequency bands. In addition, the processor 110 may significantly reduce loss caused by capacitors included in the electronic circuit 120D.

As a result, the electronic circuit system 100 according to an example embodiment may improve power efficiency in operation for transmitting signals in different frequency bands.

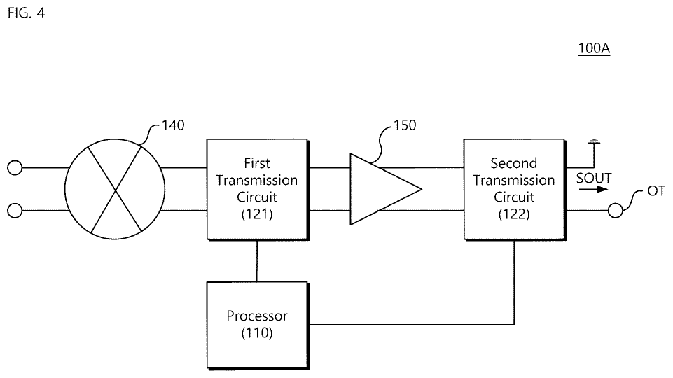

FIG. 4 is a circuit diagram illustrating an electronic circuit system including a first transmission circuit and a second transmission circuit according to an example embodiment.

Referring to FIG. 4, a transmission circuit system 100A according to an example embodiment may include a transmission mixer 140, a first transmission circuit 121, an amplifier 150, and a second transmission circuit 122.

The electronic circuit system 100A illustrated in FIG. 4 may be understood as an example of the electronic circuit system 100 of FIG. 1. Therefore, the same reference numerals are used to denote the same or substantially the same components as described above, and redundant descriptions will be omitted.

The electronic circuit system 100A may include the first transmission circuit 121 connected to the transmission mixer 140.

The first transmission circuit 121 may have substantially the same configuration as the electronic circuit 120A illustrated in FIG. 2A, the electronic circuit 120B illustrated in FIG. 2B, or the electronic circuit 120C illustrated in FIG. 2C.

For example, the first transmission circuit 121 may include a first inductor L1, connected to the transmission mixer 140, and a second inductor L2 and a third inductor L3 connected in parallel with the first inductor L1. In addition, the first transmission circuit 121 may include a first switch S1 connected between the second inductor L2 and the third inductor L3.

According to an example embodiment, the first transmission circuit 121 may be referred to as an impedance matching circuit for impedance matching for a signal transmitted from the transmission mixer 140. For example, the first transmission circuit 121 may be referred to as an inter-stage matching circuit, but example embodiments are not limited thereto.

According to an example embodiment, the signal output from the transmission mixer 140 may be converted into a signal in a predetermined frequency band through the first transmission circuit 121.

According to an example embodiment, the processor 110 may control a switch (for example, a first switch S1), included in the first transmission circuit 121, to transmit a plurality of output signals SOUT in different respective frequency bands.

Accordingly, the electronic circuit system 100A may transmit signals in different frequency bands through a single transmission structure (or a transmission (TX) chain) including the transmitter mixer 140, the first transmitter circuit 121, the amplifier 150, and the second transmitter circuit 122. As a result, the electronic circuit system 100 may have a significantly reduced area.

In addition, the electronic circuit system 100A may include a second transmission circuit 122 connected to the first transmission circuit 121 through an amplifier 150.

The second transmission circuit 122 may have substantially the same configuration as the electronic circuit 120D illustrated in FIG. 3. Therefore, redundant descriptions will be omitted.

For example, referring to FIGS. 3 and 4 together, the second transmission circuit 122 may include a first inductor L1 and a first output side inductor L21 coupled to each other.

In addition, the second transmission circuit 122 may include a second inductor L2 and a third inductor L3 connected in parallel with the first inductor L1. In addition, the second transmission circuit 122 may include a second output side inductor L22 and a third output side inductor L23 connected in parallel with the first output side inductor L21.

In addition, the second transmission circuit 122 may include a first switch S1, connected between the second inductor L2 and the third inductor L3, and an output side switch S21 connected between the second output side inductor L2 and the third output side inductor L23.

According to an example embodiment, the second transmission circuit 122 may transmit an output signal SOUT in a specified frequency band.

The second transmission circuit 122 may function as an impedance matching circuit for impedance matching between circuitry connected to the input side of the circuit 122 (e.g., the amplifier 150) and circuitry connected to the output side of the circuit 122 (e.g., a transmission line including the output terminal OT as a signal conductor, and a ground conductor). For example, the second transmission circuit 122 may be referred to as an output matching circuit connected to the output terminal OT, but example embodiments are not limited thereto.

According to an example embodiment, a signal output through the amplifier 150 may be converted into a signal having specified transmission power through the second transmission circuit 122.

The processor 110 may control one or more of the plurality of switches (for example, the first switch S1 and the output side switch S21), included in the second transmission circuit 122, to control transmission power of the output signal SOUT.

Accordingly, the electronic circuit system 100A may transmit signals having different frequency bands with different transmission powers through a single transmission structure (or, a transmission (TX) chain) including the transmission mixer 140, the first transmission circuit 121, the amplifier 150, and the second transmission circuit 122.

As a result, the electronic circuit system 100A may have a significantly reduced area.

According to an example embodiment, the first transmission circuit 121 may have or include substantially the same configuration as the second transmission circuit 122.

For example, the first transmission circuit 121 may have or include substantially the same configuration as the electronic circuit 120D illustrated in FIG. 3.

For example, the first transmission circuit 121 may include two inductors coupled to each other. In addition, the first transmission circuit 121 may include a plurality of inductors, connected in parallel with each of the two inductors coupled to each other, and switches connected between the plurality of inductors.

In addition, according to an example embodiment, the second transmission circuit 122 may have substantially the same configuration as the first transmission circuit 121.

For example, the second transmission circuit 122 may have substantially the same configuration as the electronic circuit 120A illustrated in FIG. 2A.

For example, the second transmission circuit 122 may include an inductor connected to the amplifier 150. In addition, the second transmission circuit 122 may include a plurality of inductors connected in parallel with the inductor connected to the amplifier 150. In addition, the second transmission circuit 122 may include a switch connected between a plurality of inductors.

Referring to the above-described components, the processor 110 according to an embodiment may control at least a portion of the first transmission circuit 121 and the second transmission circuit 122 to transmit output signals SOUT in different frequency bands.

In addition, the processor 110 may control at least a portion of the first transmission circuit 121 and the second transmission circuit 122 to transmit a plurality of output signals SOUT with different transmission powers.

Accordingly, the electronic circuit system 100A may transmit signals with different frequencies or different transmission powers through a single transmission structure (or, a transmission (TX) chain) including the transmission mixer 140, the first transmission circuit 121, the second transmission circuit 122, and the amplifier 150.

As a result, the electronic circuit system 100A according to an example embodiment may have a significantly reduced area.

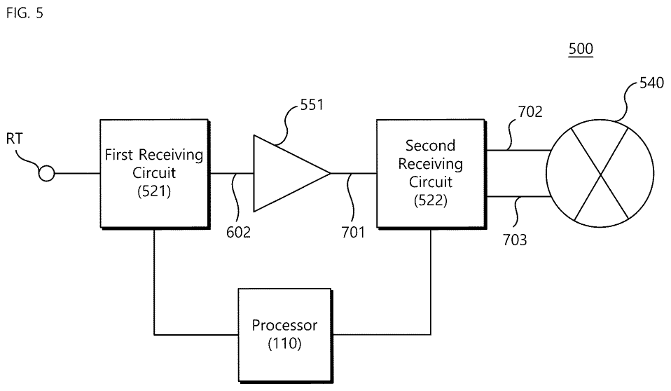

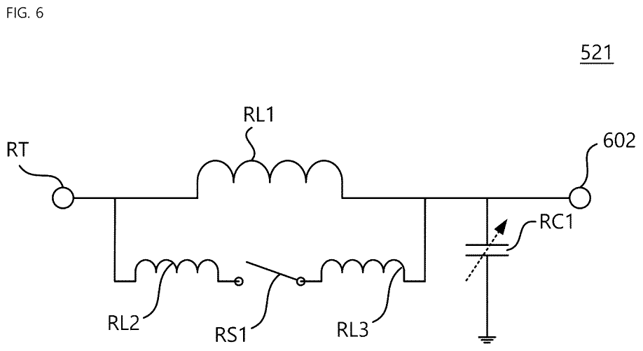

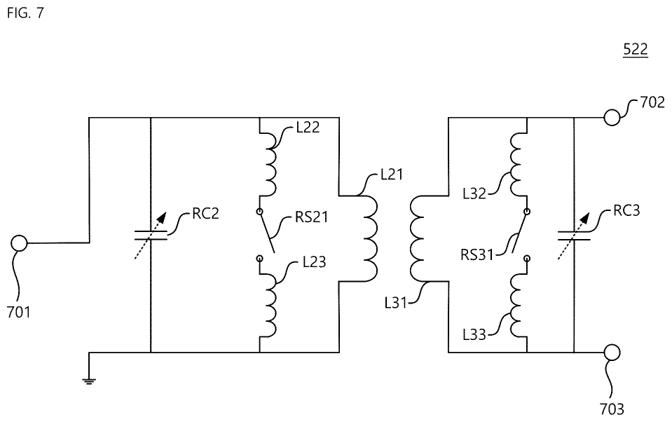

FIG. 5 is a block diagram of a receiving circuit system according to an example embodiment. FIG. 6 is a circuit diagram illustrating an example of a first receiving circuit in the receiving circuit system of FIG. 5, and FIG. 7 is a circuit diagram illustrating an example of a second receiving circuit in the receiving circuit system of FIG. 5.

Referring to FIGS. 5 to 7 together, a receiving circuit system 500 according to an embodiment may include a first receiving circuit 521 and a second receiving circuit 522 to receive signals in different frequency bands. The second receiving circuit 522 may receive an input signal at an input terminal 701 and output an output signal at an output side that includes output terminals 702 and 703.

Referring to FIG. 5, the receiving circuit system 500 according to an example embodiment may include a first receiving circuit 521, a low-noise amplifier (LNA) 551, a second receiving circuit 522, and a processor 110.

The receiving circuit system 500 may include the first receiving circuit 521 receiving an RF signal at a receiving terminal RT. For example, the first receiving circuit 521 may receive an RF signal through an antenna, connected to the receiving terminal RT, or a radio-frequency front end (RFFE), but example embodiments are not limited thereto.

The first receiving circuit 521 may function as an impedance matching circuit for impedance matching for the signal received at the receiving terminal RT (herein, “impedance matching for the signal” refers to impedance matching between circuitry at the relevant location, as noted earlier in the discussion of impedance matching in connection with FIG. 1). For example, the first receiving circuit 521 may be referred to as an input matching circuit, but example embodiments are not limited thereto.

The signal received at the receiving terminal RT may be a signal in a predetermined frequency band, and output at an output terminal 602. Furthermore, the first receiving circuit 521 may transmit a signal in a predetermined frequency band to the low-noise amplifier 551.

Referring to FIGS. 5 and 6 together, the first receiving circuit 521 according to an embodiment may include a plurality of receiving inductors RL1, RL2, and RL3. The first receiving circuit 521 of FIG. 6 may be understood as an example of the first receiving circuit 521 of FIG. 5.

For example, the first receiving circuit 521 may include a first receiving inductor RL1 connected to the receiving terminal RT. For example, the first receiving inductor RL1 may be connected to the receiving terminal RT implemented as a single terminal (which may be a signal conductor of a transmission line).

The first receiving circuit 521 may include a second receiving inductor RL2 and a third receiving inductor RL3 connected in parallel with the first receiving inductor RL1. The second receiving inductor RL2 and the third receiving inductor RL3 may be connected in series.

In addition, the first receiving circuit 521 may include a first receiving switch RS1 connected between the second receiving inductor RL2 and the third receiving inductor RL3.

According to an example embodiment, the processor 110 may control the first receiving switch RS1 such that a signal in a specified frequency band is output through the first receiving circuit 521.

For example, the processor 110 may close the first receiving switch RS1, included in the first receiving circuit 521, in response to receiving the first signal in the first frequency band (for example, about 6 GHZ) through a receiving terminal RT.

The processor 110 may receive a first signal having a first frequency band and output a signal in a specified frequency band while the first receiving switch RS1 is closed.

In addition, the processor 110 may open the first receiving switch RS1 in response to receiving a second signal in a second frequency band (for example, about 5 GHz), lower than the first frequency band, through the reception terminal RT.

The processor 110 may receive a second signal having a second frequency band and output a signal in a specified frequency band while the first receiving switch RS1 is open.

According to an example embodiment, the first receiving circuit 521 may further include a plurality of inductors connected in parallel with the first receiving inductor RL1, the second receiving inductor RL2, and the third receiving inductor RL3.

For example, the first receiving circuit 521 may include a fourth receiving inductor and a fifth receiving inductor connected in parallel with the first receiving inductor RL1, the second receiving inductor RL2, and the third receiving inductor RL3. In addition, the first receiving circuit 521 may include a second receiving switch connected between the fourth receiving inductor and the fifth receiving inductor.

In this case, the processor 110 may control at least a portion of the first receiving switch RS1 and the second receiving switch to receive signals in different frequency bands.

However, the number and configuration of inductors connected in parallel with the first receiving inductor RL1 are not limited to the above-described examples.

Referring to the above-described configuration, the processor 110 according to an example embodiment may receive signals having different frequency bands. Furthermore, the processor 110 may control the first receiving switch RS1, included in the first reception circuit 521, to receive signals having different frequency bands.

Accordingly, the receiving circuit system 500 may receive signals in different frequency bands through a single receiving structure (or a receiving (RX) chain) including the first receiving circuit 521, the second receiving circuit 522, the low-noise amplifier 551, and the receiving mixer 540.

As a result, the receiving circuit system 500 may have a significantly reduced area.

In addition, according to an example embodiment, the first receiving circuit 521 may further include a first receiving capacitor RC1 connected between the first receiving inductor RL1 and ground.

For example, the first receiving circuit 521 may include a first receiving capacitor RC1 connected to at least a portion of the first receiving inductor RL1, the second receiving inductor RL2, and the third receiving inductor RL3.

For example, the first receiving circuit 521 may include a first receiving capacitor RC1 connected in series between the first receiving inductor RL1 and the ground while the first receiving switch RS1 is open.

In addition, the first receiving circuit 521 may include a first receiving capacitor RC1 connected to the first receiving inductor RL1, the second receiving inductor RL2, and the third receiving inductor RL3 while the first receiving switch RS1 is closed.

According to an example embodiment, the processor 110 may control the capacitance of the first receiving capacitor RC1, included in the first receiving circuit 521, such that a signal in the specified frequency band is output through the first receiving circuit 521.

For example, the processor 110 may control the capacitance of the first receiving capacitor RC1 such that the first receiving capacitor RC1 resonates with at least one of the inductors connected to the first receiving capacitor RC1.

For example, the processor 110 may control the capacitance of the first receiving capacitor RC1 to first capacitance such that the first receiving capacitor RC1 resonates with the first receiving inductor RL1, the second receiving inductor RL2, and the third receiving inductor RL3 while first receiving switch S1 is closed.

In addition, the processor 110 may control the capacitance of the first receiving capacitor RC1 to second capacitance, lower than the first capacitance, such that the first receiving capacitor RC1 resonates with the first receiving inductor RL1 while the first receiving switch S1 is open.

Referring to the above-described components, the processor 110 according to an example embodiment may control the capacitance of the first receiving capacitor RC1 based on an inductance value of the first receiving circuit 521 controlled by the first receiving switch S1.

As a result, the processor 110 may increase an impedance value of the first receiving circuit 521. In addition, the receiving circuit system 500 according to an example embodiment may improve a frequency gain of the first receiving circuit 521.

In addition, the processor 110 may significantly decrease the number and/or size of capacitors required in the first receiving circuit 521 to receive signals in different frequency bands. In addition, the processor 110 may significantly reduce loss caused by the capacitors included in the first receiving circuit 521.

As a result, the receiving circuit system 500 according to an example embodiment may improve power efficiency of an operation for receiving signals in different frequency bands.

Referring to FIGS. 5 and 7 together, the second receiving circuit 522 according to an example embodiment may include inductors, coupled to each other, and a plurality of inductors, respectively connected in parallel with the inductors.

The second receiving circuit 522 illustrated in FIG. 7 may be understood as an example of the second receiving circuit 522 of FIG. 5.

In an example embodiment, the second receiving circuit 522 may include a receiving inductor L22 and a receiving inductor L23 connected in parallel with a receiving inductor L21. The receiving inductor L22 and the receiving inductor L23 may be connected in series.

In addition, the second receiving circuit 522 may include a receiving switch RS21 connected between the receiving inductor L22 and the receiving inductor L23.

The second receiving circuit 522 may further include a receiving inductor L31 coupled to the 2-1-th receiving inductor L21.

In addition, the second receiving circuit 522 may include a receiving inductor L32 and a receiving inductor L33 connected in parallel to the receiving inductor L31. The receiving inductor L32 and the receiving inductor L33 may be connected in series.

In addition, the second receiving circuit 522 may include a receiving switch RS31 connected between the receiving inductor L32 and the receiving inductor L33.

The second receiving circuit 522 may be referred to as an impedance matching circuit for impedance matching for a signal received through the low-noise amplifier 551. For example, the second receiving circuit 522 may be referred to as an inter-stage matching circuit, but example embodiments are not limited thereto.

In an example embodiment, the processor 110 may control at least a portion of the receiving switch RS21 and the switch RS31, included in the second receiving circuit 522, such that the signal received through the receiving terminal RT (or the low-noise amplifier 551 is output through the second receiving circuit 522 with specified receiving power.

For example, the processor 110 may open the receiving switch RS21, included in the second receiving circuit 522, in response to receiving a signal with first receiving power through the receiving terminal RT.

In addition, the processor 110 may close the receiving switch RS21 included in the second receiving circuit 522 in response to receiving a signal with second receiving power, lower than the first receiving power, through the receiving terminal RT.

For example, the processor 110 may close the receiving switch RS1 to increase power of the signal output through the second receiving circuit 522. In addition, the processor 110 may open the receiving switch RS21 to decrease the power of the signal output through the second receiving circuit 522.

For example, the processor 110 may open the receiving switch RS31 included in the second receiving circuit 522 in response to a request to increase the power of the signal output through the second receiving circuit 522.

The processor 110 may close the receiving switch RS31 included in the second receiving circuit 522 in response to a request to decrease the power of the signal output through the second receiving circuit 522.

For example, the processor 110 may open the receiver switch RS31 to increase the power of the signal output through the second receiving circuit 522. In addition, the processor 110 may close the receiver switch RS31 to decrease the power of the signal output through the second receiving circuit 522.

For example, the processor 110 may close the receiver switch RS21 and open the receiver switch RS31 in response to a request to increase the power of the signal output through the second receiving circuit 522.

In addition, the processor 110 may open the receiver switch RS21 and close the receiver switch RS31 in response to a request to decrease the power of the output signal output SOUT.

Referring to the above-described components, the processor 110 may control at least a portion of the receiver switch RS21 and the receiver switch RS31 to control the power of the signal output through the second receiving circuit 522.

As a result, the receiving circuit system 500 according to an example embodiment may improve power efficiency of an operation for receiving signals received with different receive power.

The receiving circuit system 500 may include a receiving mixer configured to down-convert a signal received through the second receiving circuit 522.

For example, the receiving mixer 540 may down-convert the signal received through the second receiving circuit 522 into a baseband signal based on the signal received from a local oscillator LO.

Referring to the above-described components, the processor 110 may control at least a portion of the first receiving circuit 521 and the second receiving circuit 522 to receive signals with different frequency bands as baseband signals after being converted.

Accordingly, the receiving circuit system 500 may receive signals in different frequency bands through a single receiving structure (or, an RX chain) including the first receiving circuit 521, the second receiving circuit 522, the low-noise amplifier 551, and the receiving mixer 540.

In addition, the processor 110 may control at least a portion of the first receiving circuit 521 and the second receiving circuit 522 to receive different signals, received with different receiving powers, as signals with specified power after being converted.

Accordingly, the receiving circuit system 500 may receive signals with different powers through a single receive structure (or, an RX chain) including the first receiving circuit 521, the second receiving circuit 522, and the receiving mixer 540.

According to the above-described components, the receiving circuit system 500 may have a significantly reduced area.

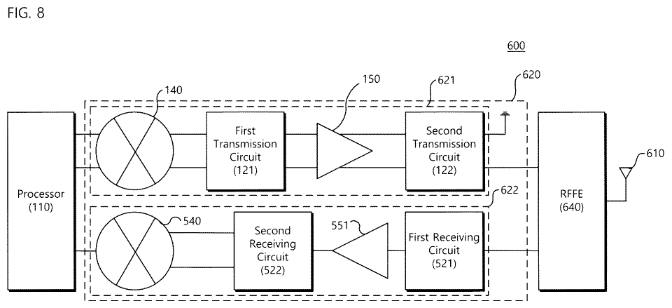

FIG. 8 is a block diagram of an electronic circuit system according to an example embodiment.

Referring to FIG. 8, a electronic circuit system 600 according to an example embodiment may include a radio-frequency integrated circuit (RFIC) 620, a processor 110, a radio-frequency front end (RFFE) 640, and an antenna 610.

The electronic circuit system 600 may include the RFFE 640 transmitting or receiving an RF signal through the antenna 610.

In some embodiments, the antenna 610 is an array antenna including a plurality of antenna elements for transmitting and/or receiving. In other embodiments, the antenna 610 has a single antenna element for transmitting and receiving, or has a first antenna element for transmitting and a second antenna element for receiving.

The antenna 610 may be implemented as a single antenna transmitting and receiving RF signals of a specified frequency band. For example, the antenna 610 may include an antenna for transmitting an RF signal and an antenna for receiving an RF signal as components separate from each other.

In an example embodiment, the RFFE 640 may transmit and/or receive a plurality of RF signals in different frequency bands through the antenna 610.

Furthermore, the RFFE 640 may perform pre-processing on signals received through the antenna 610. For example, the RFFE 640 may pre-process an RF signal received through the antenna 610.

To this end, the RFFE 640 may include a phase shifter, a band pass filter, and/or a switching circuit that are connected to the antenna 610.

The RFFE 640 may transmit an RF signal, received from the antenna 610, to the RFIC 620. The RFFE 640 may also transmit an RF signal, transmitted from the RFIC 620, to the antenna 610.

The electronic circuit system 600 may include an RFIC 620 connected between the RFFE 640 and the processor 110.

The electronic circuit system 600 may include the RFIC 620 converting a baseband signal into an RF signal or converting an RF signal into a baseband signal.

The RFIC 620 may convert the RF signal, pre-processed through the RFFE 640, into a baseband signal to be processed by the processor 110 when receiving the RF signal.

For example, the RFIC 620 may convert the baseband signal, generated by the processor 110, into an RF signal of about 700 MHz to about 3 GHz used in a first network (for example, a legacy network) when transmitting the baseband signal.

For example, the RFIC 620 may convert the baseband signal, generated by the processor 110, into an RF signal of the Sub6 band (less than about 6 GHz) used in a second network (for example, a 5G network) when transmitting the baseband signal.

For example, the RFIC 620 may convert the baseband signal, generated by the processor 110, into an RF signal of the 5G Above5 band (about 6 GHz to about 60 GHz) used in a third network (for example, a 5G network) when transmitting the baseband signal.

According to an example embodiment, the RFIC 620 may include a transceiver that includes a transmission circuit 621 and a receiver 622.

The transmitting circuit 621 with the processor 110 illustrated in FIG. 8 may have the same configuration as the electronic circuit system 100A of FIG. 4. Alternatively, the transmission circuit 621 may have the same configuration as the electronic circuit system 100 of FIG. 1.

In addition, the receiver 622 illustrated in FIG. 8 may have the same configuration as the electronic circuit system 500 of FIG. 5.

Therefore, the same reference numerals were used to denote the same or substantially the same components, and redundant descriptions are omitted.

In an example embodiment, the processor 110 may control at least a portion of a first transmission circuit 121 and a second transmission circuit 122 of the transmission circuit 621 to transmit signals in different frequency bands through the antenna 610.

For example, the processor 110 may control at least portion of switches, included in the first transmission circuit 121 and the second transmission circuit 122 of the transmission circuit 621, to transmit signals in different frequency bands through the antenna 610.

In addition, the processor 110 may control at least a portion of the first transmission circuit 121 and the second transmission circuit 122 of the transmission circuit 621 to transmit signals in different frequency bands through the antenna 610 with different transmit powers.

As a result, the electronic circuit system 600 according to an example embodiment may transmit signals in different frequency bands with different transmit powers using a single transmission circuit 621.

In addition, the processor 110 according to an example embodiment may control at least a portion of the first receiving circuit 521 and the second receiving circuit 522 of the receiver 622 to receive signals in different frequency bands through the antenna 610.

For example, the processor 110 may control at least one of the switches included in the first receiving circuit 521 and the second receiving circuit 522 of the receiver 622 to receive signals in different frequency bands through the antenna 610.

Accordingly, the electronic circuit system 600 may receive signals in different frequency bands through a single receiver 622 including the first receiving circuit 521, the second receiving circuit 522, and the receiving mixer 540.

In addition, the processor 110 may control at least a portion of the first receiving circuit 521 and the second receiving circuit 522 to receive signals with different receive powers.

Thus, the electronic circuit system 600 may receive signals with different powers through a single receiver 622 including the first receiving circuit 521, the second receiving circuit 522, and the receiver mixer 540.

According to the above-described components, the electronic circuit system 600 according to an example embodiment may have a significantly reduced area.

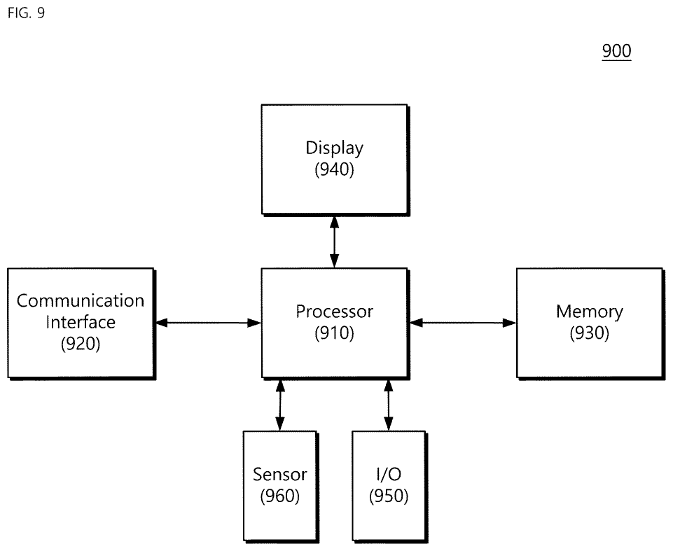

FIG. 9 is a block diagram of an IoT device including an electronic circuit system according to an example embodiment.

Referring to FIG. 9, Internet of Things (IoT) may refer to a network between things using wired or wireless communications. IoT devices may include devices having accessible wired or wireless interfaces and communicating with one or more other devices through the wired or wireless interfaces to transmit or receive data. In IoT devices, accessible interfaces may include wired local area network (LAN), wireless local area network (WLAN) such as Wi-Fi, wireless personal area network (WPAN) such as Bluetooth, wireless universal serial bus (wireless USB), Zigbee, near field communication (NFC), radio-frequency identification (RFID), power line communication (PLC), or a modem communication interface capable of connecting to mobile cellular networks such as 3G, LTE, 4G, or 5G. The Bluetooth interfaces may support Bluetooth low energy (BLE).

For example, an IoT device 900 may include a communication interface 920 for communication with an external entity. The communication interface 920 may be, for example, a wired local area network (LAN), Bluetooth, Wi-Fi, Zigbee, PLC, or a modem communication interface capable of connecting to mobile cellular networks such as 3G, LTE, 4G, or 5G.

The communication interface 920 may include a transceiver and/or a receiver. The communication interface 920 illustrated in FIG. 9 may be understood to have substantially the same configuration as the RFIC 620 of FIG. 8. For example, the communication interface 920 of FIG. 9 may include the transmission circuit 621 and the receiver 622 of FIG. 8.

The IoT device 900 may transmit and/or receive information from and/or to an access point or a gateway through the transmitter and/or the receiver. In addition, the IoT device 900 may communicate with a user device or another IoT device to transmit and/or receive control information or data of the IoT device 900.

The IoT device 900 may include a processor 910 performing operations. The processor 910 illustrated in FIG. 9 may be referred to as having substantially the same configuration as the processor 110 illustrated in FIGS. 1 to 8.

According to an example embodiment, the processor 910 may control at least one switch, included in the communication interface 920, such that the IoT device 900 transmits and/or receives signals in different frequency bands.

The IoT device 900 may be powered internally by a battery or externally through a power supply. In addition, the IoT device 900 may include a display 940 configured to display an internal status or data. A user may control the IoT device 900 through a user interface (UI) of the display 940 of the IoT device 900. The IoT device 900 may transmit an internal status and/or data to an external entity through the transmitter, and may receive a control command and/or data from an external entity through the receiver.

The memory 930 may store control a command code, control data, or user data controlling the IoT device 900. The memory 930 may include at least one selected from a volatile memory and a nonvolatile memory. The nonvolatile memory may include at least one of various memories such as a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (ReRAM), or a ferroelectric RAM (FRAM). The volatile memory may include at least one of various memories such as a dynamic RAM (DRAM), a static RAM (SRAM), or a synchronous DRAM (SDRAM).

The IoT device 900 may further include a storage device. The storage device may include at least one of nonvolatile media such as a hard disk (HDD), a solid state drive (SDD), an embedded multimedia card (eMMC), and a universal flash storage (USF). The storage device may store user information provided through an input/output unit (I/O) 950 and a plurality of pieces of sensing information collected through the sensor 960.

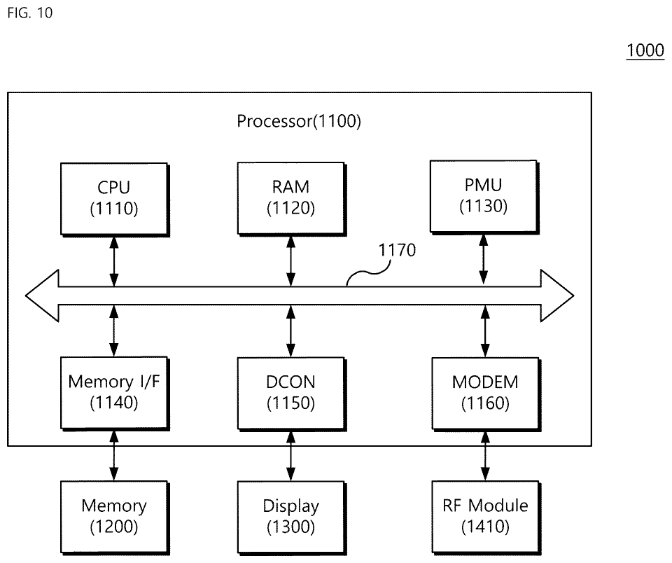

FIG. 10 is a block diagram of a mobile terminal, 1000, to which an electronic circuit system according to an example embodiment is applied. The mobile terminal 1000 may include a processor 1100, a memory 1200, a display 1300, and a radio-frequency (RF) module 1410. In addition, the mobile terminal 1000 may further include various components such as a lens, a sensor, or an audio module.

The processor 1100 may be implemented as a system-on-chip (SoC), and may include a central processing unit (CPU) 1110, a RAM 1120, a power management unit (PMU) 1130, a memory interface (Memory I/F) 1140, a display controller (DCON) 1150, a modem 1160, and a bus 1170. The processor 1100 may further include various IPs. The processor 1100 may be referred to as “ModAP” as a function of a modem chip is integrated therein, but example embodiments are not limited thereto.

The processor 1100 illustrated in FIG. 10 may have substantially the same configuration and functionality as the processor 110 of FIGS. 1 to 8.

The CPU 1110 may control the overall operation of the processor 1100 and the mobile terminal 1000. The CPU 1110 may control the operation of each component of processor 1100. The CPU 1110 may be implemented as a multi-core processor. The multi-core processor is a computing component having two or more independent cores.

The RAM 1120 may temporarily store programs, data, or instructions. For example, programs and/or data stored in the memory 1200 may be temporarily stored in the RAM 1120 according to the control of the CPU 1110 or a booting code. The RAM 1120 may be implemented as a DRAM or an SRAM.

The PMU 1130 may manage the power of each component of the processor 1100. The PMU 1130 may also determine an operational status of each component of the processor 1100, and may control an operation of the component.

The memory interface 1140 may control the overall operation of the memory 1200 and may control data exchange between each component of the processor 1100 and the memory 1200. The memory interface 1140 may write data in the memory 1200 or read data from the memory 1200 based on a request of the CPU 1110.

The display controller 1150 may transmit image data to be displayed on the display 1300 to the display 1300. The display 1300 may be implemented as a flat panel display or a flexible display, such as a liquid crystal display (LCD) and an organic light emitting diode (OLED).

The modem 1160 may modulate data to be transmitted in a wireless environment suitable for wireless communication, and may recover received data. The modem 1160 may perform digital communication with the RF module 1410.

The RF module 1400 may convert a high-frequency signal, received via an antenna, into a low-frequency signal and provide the low-frequency signal to the modem 1160. The RF module 1410 may convert a low-frequency signal, received from the modem 1160, into a high-frequency signal and transmit the high-frequency signal to free space outside the mobile terminal 1000 via the antenna. The RF module 1160 may amplify or filter a signal.

The RF module 1410 illustrated in FIG. 10 may be referred to as having substantially the same configuration as the electronic circuit system 600 illustrated in FIG. 8. Therefore, the RF module 1410 may include switches connected to a plurality of inductors.

The processor 1100 may control an electronic circuit (for example, the electronic circuit 120A of FIG. 2A) included in the RF module 1410 such that the mobile terminal 1000 transmits and/or receives signals in different frequency bands.

For example, the processor 1100 may control at least one switch, included in the electronic circuit of the RF module 1410, to transmit or receive signals in different frequency bands to or from free space outside of the mobile terminal 1000.

As a result, the mobile terminal 1000 may support broadband communication while reducing power consumption for broadband communication.

As described above, the processor 110 according to an example embodiment may control a switch, connected to a plurality of inductors in at least one electronic circuit, to transmit signals in different frequency bands.

Accordingly, the electronic circuit system 100 according to an example embodiment may transmit signals in different frequency bands through a single transmission structure.

In addition, the processor 110 according to an example embodiment may control a switch, connected to a plurality of inductors in at least one electronic circuit, to receive signals in different frequency bands.

Accordingly, the receiving circuit system 500 according to an example embodiment may receive signals in different frequency bands through a single receiving structure.

As a result, the electronic circuit system 100, the receiving circuit system 500, and the electronic circuit system 600 according to respective example embodiments may each have a significantly reduced area.

In addition, the processor 110 according to an example embodiment may control capacitance of a variable capacitor based on inductance of the electronic circuit controlled through the switch.

Accordingly, the processor 110 may significantly decrease the number and/or size of capacitors used in the electronic circuit (e.g., relative to those in related art circuits) to transmit signals in different frequency bands. In addition, the processor 110 may significantly reduce loss caused by capacitors included in the electronic circuit.

As a result, the transmitting circuit system 100 according to an example embodiment may improve power efficiency of an operation for transmitting signals in different frequency bands or with different transmission powers.

As set forth above, an electronic circuit according to example embodiments may control a switch, connected to an inductor, to transmit and/or receive signals in different frequency bands.

As a result, the electronic circuit may occupy a significantly reduced area.

While example embodiments have been shown and described above, it will be apparent to those skilled in the art that modifications and variations could be made without departing from the scope of the present inventive concept as defined by the appended claims.

What is claimed is:

1. An electronic circuit comprising:
a first inductor connected to an input terminal;
a second inductor and a third inductor connected in series and connected in parallel with the first inductor;
a first switch connected between the second inductor and the third inductor; and
a processor electrically connected to the first switch,
wherein the processor is configured to:
close the first switch in response to a first request such that a first signal in a first frequency band is output through an output side of the electronic circuit; and
open the first switch in response to a second request, distinct from the first request, such that a second signal in a second frequency band, lower than the first frequency band, is output through the output side.

2. The electronic circuit of claim 1, further comprising:
a variable capacitor connected to the first inductor, the second inductor, and the third inductor,
wherein the processor controls capacitance of the variable capacitor such that the variable capacitor resonates with at least one of the first to third inductors connected to the variable capacitor.

3. The electronic circuit of claim 2, wherein the processor is configured to:
control the capacitance of the variable capacitor to a first capacitance such that the variable capacitor resonates with the first to third inductors while the first switch is closed; and
control the capacitance of the variable capacitor to a second capacitance, lower than the first capacitance, such that the variable capacitance resonates with the first inductor while the first switch is open.

4. The electronic circuit of claim 2, wherein the first, second, and third inductors are input side inductors, and the electronic circuit further comprising:
a first output side inductor electromagnetically coupled to the first inductor;
a second output side inductor and a third output side inductor connected in series and connected in parallel to the first output side inductor; and
an output side switch connected between the second output side inductor and the third output side inductor,
wherein the processor is configured to:
close the first switch in response to a request to increase transmission power of a transmission signal; and
open the first switch and close the output side switch in response to a request to decrease the transmission power of the transmission signal.

5. The electronic circuit of claim 4, wherein
the process is configured to:
open the output side switch in response to the request to increase the transmission power of the transmission signal; and
close the output side switch in response to the request to decrease the transmission power of the transmission signal.

6. The electronic circuit of claim 4, further comprising:
an output side variable capacitor connected to the first output side inductor, the second output side inductor, and the third output side inductor,
wherein the processor controls capacitance of the output side variable capacitor such that the output side variable capacitor resonates with at least one of the output side inductors, among output side inductors connected to the output side variable capacitor.

7. The electronic circuit of claim 1, wherein the switch is a first switch, and the electronic circuit further comprising:
a fourth inductor and a fifth inductor connected in parallel with the first inductor and connected in series; and
a second switch connected between the fourth inductor and the fifth inductor,
wherein the processor closes the first switch and the second switch in response to a third request such that a third signal in a third frequency band, higher than the first frequency band, is output through the output side.

8. The electronic circuit of claim 7, wherein the processor opens the first switch and closes the second switch in response to a fourth request such that a fourth signal in a fourth frequency band, higher than the first frequency band and lower than the third frequency band, is output through the output side.

9. The electronic circuit of claim 1, further comprising:
a transmission mixer connected to the first inductor through the input terminal and configured to up-convert a baseband signal; and
an amplifier configured to amplify the first or second signal output through the output side,
wherein the baseband signal up-converted through the transmission mixer is applied to the first inductor through the input terminal.

10. A electronic circuit system comprising an electronic circuit, the system comprising:
a transmission mixer configured to up-convert a baseband signal;
a first transmission circuit configured to receive a signal up-converted from the baseband signal by the transmission mixer;
an amplifier configured to amplify a signal output from the first transmission circuit and to output the amplified signal;
a second transmission circuit having an output side and receiving an amplified signal from the amplifier; and
a processor electrically connected to the first transmission circuit and the second transmission circuit,
wherein the first transmission circuit comprises:
a first inductor;
a second inductor and a third inductor connected in parallel with the first inductor and connected in series; and
a first switch connected between the second inductor and the third inductor, and
the processor controls the first switch such that signals in different frequency bands are output through the output side.

11. The electronic circuit system of claim 10, wherein
the processor is configured to:
close the first switch in response to a first request such that a first signal in a first frequency band is output through the output side; and
open the first switch in response to a second request, distinct from the first request, such that a second signal in a second frequency band, lower than the first frequency band, is transmitted through the output side.

12. The electronic circuit system of claim 11, wherein
the first transmission circuit comprises a variable capacitor connected to the first inductor, the second inductor, and the third inductor, and
the processor controls capacitance of the variable capacitor such that the variable capacitor resonates with at least one inductor connected to the variable capacitor.

13. The electronic circuit system of claim 11, wherein the switch is the first switch and the first transmission circuit comprises:
a fourth inductor and a fifth inductor connected in parallel with the first inductor and connected in series; and
a second switch connected between the fourth inductor and the fifth inductor, and
the processor closes the first switch and the second switch in response to a third request such that a third signal in a third frequency band, higher than the first frequency band, is transmitted through the output side.

14. The electronic circuit system of claim 11, wherein
the second transmission circuit comprises:
a first output inductor connected to the amplifier;
a second output inductor and a third output inductor connected in parallel to the first output inductor and connected in series; and
a first output switch disposed between the second output inductor and the third output inductor, and
the processor controls at least a portion of the first switch and the first output switch such that signals in different frequency bands are output through the output side.

15. The electronic circuit system of claim 14, wherein
the second transmission circuit comprises:
a fourth output inductor coupled to the first output inductor;
a fifth output inductor and a sixth output inductor connected in parallel to the fourth output inductor; and
a second output switch connected between the fifth output inductor and the sixth output inductor, and
the processor controls at least a portion of the first output switch and the second output switch to change inductance of the second transmission circuit such that a signal transmitted through the amplifier is transmitted with a specified frequency band through the output side.

16. A receiving circuit system comprising:
a first receiving circuit configured to receive a radio-frequency (RF) signal at a receiving terminal;
a low-noise amplifier configured to amplify a signal output from the first receiving circuit;
a second receiving circuit configured to receive a signal amplified by the low-noise amplifier;
a receiving mixer configured to down-convert a signal, output from the second receiving circuit, into a baseband signal; and
a processor connected to the first receiving circuit and the second receiving circuit,
wherein the first receiving circuit comprises:
a first receiving inductor;
a second receiving inductor and a third receiving inductor connected in parallel with the first receiving inductor; and
a first receiving switch connected between the second receiving inductor and the third receiving inductor, wherein the second and third receiving inductors are connected in series when the receiving switch is closed, and
the processor controls the first receiving switch to change inductance of the first receiving circuit such that signals in different frequency bands, received at the receiving terminal, are output by the first receiving circuit.

17. The receiving circuit system of claim 16, wherein
the processor is configured to:
close the first receiving switch in response to receiving a first signal in a first frequency band at the receiving terminal; and
open the receiving switch in response to receiving a second signal in a second frequency band, lower than the first frequency band, at the receiving terminal.

18. The receiving circuit system of claim 17, wherein the receiving switch is a first receiving switch, and the first receiving circuit further comprises:
a fourth receiving inductor and a fifth receiving inductor connected in parallel with the first receiving inductor and connected in series with each other; and
a second receiving switch connected between the first receiving inductor and the fifth receiving inductor, and
the processor closes the first receiving switch and the second receiving switch in response to a third request such that a third signal in a third frequency band, higher than the first frequency band, is output by the first receiving circuit.

19. The receiving circuit system of claim 16, wherein
the second receiving circuit comprises:
a first input inductor connected to the low-noise amplifier;
a second input inductor and a third input inductor connected in parallel to the first input inductor; and
a first input switch disposed between the second input inductor and the third input inductor, and
the processor controls at least one of the first receiving switch and the first input switch such that signals in different frequency bands are output by the second receiving circuit.

20. The receiving circuit system of claim 17, wherein
the first receiving circuit comprises a first receiving capacitor connected between the first receiving inductor and ground, and
the processor controls capacitance of the first receiving capacitor such that the first receiving capacitor resonates with at least one receiving inductor connected to the first receiving capacitor.
